(19) United States
(12) Patent Application Publication
(10) Pub. No.: US 2022/0384704 A1
(43) Pub. Date: Dec. 1, 2022

(54) INTEGRATION SCHEME FOR SHUNTED JOSEPHSON JUNCTIONS

(71) Applicant: Microsoft Technology Licensing, LLC, Redmond, WA (US)

(72) Inventors: Richard P. ROUSE, Seattle, WA (US); Karthik JAMBUNATHAN, Kirkland, WA (US); Susan E. SHORE, Redmond, WA (US); Jeremy WARREN, Apple Valley, MN (US); Manan PATEL, Plymouth, MN (US); Brian BENTON, Minnetonka, MN (US); Kan MI, Eden Prairie, MN (US); Kenneth FLUGAUR, Shakopee, MN (US); Alexander CHOV, Minneapolis, MN (US); Bryan SMITH, Rose Mountain, MN (US)

(21) Appl. No.: 17/333,183

(22) Filed: May 28, 2021

(51) Int. Cl. H01L 39/22; H01L 39/02; H01L 39/24

(52) U.S. Cl. CPC H01L 39/223; H01L 39/025; H01L 39/2493

(57) ABSTRACT

Materials with etch selectivity with respect to one another and one or more additional etch-stop layers are used in a Josephson junction structure to allow for integration with a Josephson junction with supporting structures such as resistors. Selective etch processes compatible with high volume manufacturing are used to pattern various layers of the Josephson junction structure to provide a Josephson junction, which is electrically coupled to a support structure.

### FIELD OF THE DISCLOSURE

The present disclosure is related to Josephson junctions, and in particular to Josephson junctions including a shunt resistor and methods for manufacturing the same.

### BACKGROUND

A Josephson junction includes a non-superconducting material sandwiched between two layers of superconducting material. Josephson junctions can be used to build electronic circuitry, and in particular logic circuitry and quantum computing circuitry. Further, Josephson junctions can be arranged to provide superconducting quantum interference devices (SQUIDs), which can be used for extremely sensitive measurement tools. Integrating one or more Josephson junctions along with other circuitry may require supporting components such as a shunt resistor. Generally, it is desirable to integrate these supporting components along with the Josephson junctions. However, processes for fabricating Josephson junctions including one or more support components have generally been defined by low volume, complex fabrication techniques. As demand for circuitry including Josephson junctions continues to increase, there is a need for Josephson junctions integrated with supporting components and processes for providing these Josephson junctions using high volume manufacturing techniques.

### SUMMARY

In one embodiment, a method for manufacturing a Josephson junction structure begins with providing a substrate. An insulating layer is provided on the substrate. A support structure is on the insulating layer. A wetting layer is provided on the insulating layer and the support structure. An etch-stop layer is provided on the wetting layer. A base metal layer is provided on the etch-stop layer. The base metal layer comprises a superconducting material and is in electrical contact with the support structure via the etch-stop layer and the wetting layer. A middle layer is provided on the base metal layer. The middle layer comprises an insulating material. A top metal layer is provided on the middle layer. The top metal layer comprises a superconducting material. The top metal layer is patterned with a first etch process that is selective with respect to the middle layer. The middle layer is patterned with a second etch process that is selective with respect to the base metal layer. The base metal layer is patterned with a third etch process that is selective with respect to the etch-stop layer. The etch-stop layer and the wetting layer are patterned with a fourth etch process that is selective with respect to the support structure. The base metal layer, the middle layer, and the top metal layer are patterned such that they provide a Josephson junction that is electrically coupled to the support structure. Providing the etch-stop layer and the wetting layer allows the materials for the support structure and the base metal layer to be chosen independently of their etch selectivity with respect to one another. Providing the etch-stop layer and the wetting layer and patterning the layers using selective etch processes, the Josephson junction structure can be manufactured using high volume manufacturing techniques.

In one embodiment, the support structure is a resistor. The resistor may be a shunt resistor. In various embodiments, the resistor comprises one of titanium tungsten and tungsten. The wetting layer comprises titanium. The etch-stop layer comprises aluminum. The base metal layer and the top metal layer comprise niobium. The middle layer comprises aluminum oxide.

The first etch process and the third etch process may utilize an etching solution comprising fluorine. The second etch process and the fourth etch process may utilize an etching solution comprising chlorine.

In one embodiment, a Josephson junction structure includes a substrate, an insulating layer, a wetting layer, an etch-stop layer, a base metal layer, a middle layer, and a top metal layer. The insulating layer is on the substrate. The support structure is on the insulating layer. The wetting layer is on the insulating layer and the support structure. The etch-stop layer is on the wetting layer. The base metal layer is on the etch-stop layer. The base metal layer comprises a superconducting material and is in electrical contact with the support structure via the etch-stop layer and the wetting layer. The middle layer is on the base layer and comprises a non-superconducting material. The top metal layer is on the middle layer and comprises a superconducting material. Providing the etch-stop layer and the wetting layer allows the materials for the support structure and the base metal layer to be chosen independently of their etch selectivity with respect to one another.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a Josephson junction structure according to one embodiment of the present disclosure.

FIG. 2 is a cross-sectional view of a Josephson junction structure according to one embodiment of the present disclosure.

FIG. 3 is a flow diagram illustrating a method for manufacturing a Josephson junction structure according to one embodiment of the present disclosure.

FIGS. 4A through 4N are cross-sectional views of a Josephson junction throughout a manufacturing process thereof according to one embodiment of the present disclosure.

FIG. 5 is a cross-sectional view of a Josephson junction structure according to one embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

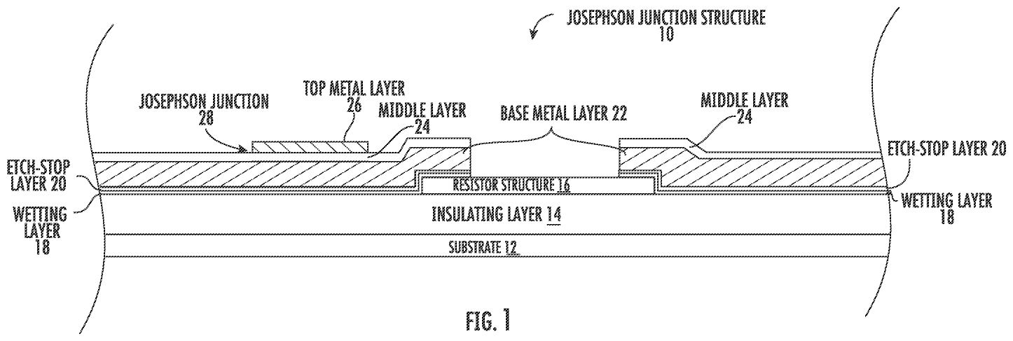

FIG. 1 shows a cross-sectional view of a Josephson junction structure 10 including an integrated shunt resistor according to one embodiment of the present disclosure. The Josephson junction structure 10 includes a substrate 12, an insulating layer 14 on the substrate 12, a resistor structure 16 on the insulating layer 14, a wetting layer 18 on the insulating layer 14 and a portion of the resistor structure 16, an etch-stop layer 20 on the wetting layer 18, a base metal layer 22 on the etch-stop layer 20, a middle layer 24 on the base metal layer 22, and a top metal layer 26 on the middle layer 24. As shown, the wetting layer 18, the etch-stop layer 20, and the base metal layer 22 are patterned into separate sections that are separated by the resistor structure 16. The middle layer 24 and the top metal layer 26 are patterned in a desired shape to form a Josephson junction 28 including the base metal layer 22, the middle layer 24, and the top metal layer 26.

As discussed in detail below, the materials for the resistor structure 16, the wetting layer 18, the etch-stop layer 20, the base metal layer 22, the middle layer 24, and the top metal layer 26 are chosen not only for one or more electrical characteristics thereof (e.g., superconducting, non-superconducting, resistivity, etc.), but also for their selectivity with respect to one another in certain etch processes used to form the Josephson junction structure 10. In particular, etch processes for the base metal layer 22 and the top metal layer 26 are selective with respect to the middle layer 24 and the etch-stop layer 20, and vice-versa. Similarly, etch processes for the etch-stop layer 20 and the wetting layer 18 are selective with respect to the resistor structure 16. As defined herein, an etch process is selective between materials when the etching rate of the etching process between the material for which etching is not desired (e.g., a lower layer) and a material for which etching is desired (e.g., an upper layer) is less than 1. In some embodiments, however, the etching rate between the material for which etching is not desired and the material for which etching is desired may be less than 0.75, less than 0.5, and less than 0.1.

To satisfy the above requirements, the resistor structure 16 may comprise titanium tungsten (TiW) or tungsten. However, the resistor structure 16 may also comprise any other suitable material, and in various embodiments can comprise any non-superconducting metal that is not magnetic and is also selective in an etch process with respect to the etch-stop layer 20 and the wetting layer 18. Previously, the base metal layer 22 was provided directly on the resistor structure 16. Such a structure required etch selectivity between the base metal layer 22 and the resistor structure 16. Due to the superconducting requirements of the base metal layer 22 to provide the Josephson junction 28, the materials available for the resistor structure 16 were very limited (e.g., to noble metals including gold that have a low sheet resistivity). Due to the low sheet resistivity of the materials available for the resistor structure 16, a large area or footprint was required to achieve a desired resistance. The use of the wetting layer 18 and the etch-stop layer 20 described herein effectively decouples the etch selectivity requirements of the base metal layer 22 and the resistor structure 16, which enables the use of additional categories of materials for the resistor structure 16. In particular, this may enable the use of materials with a high sheet resistivity for the resistor structure 16. As a result, the resistor structure 16 can have a much smaller area or footprint compared to previous approaches while providing a desired resistance. In one embodiment, an area of the resistor structure 16 may be less than 90 μm², and may be as low as 10 nm² in some embodiments.

As discussed above, to provide the Josephson junction 28 the base metal layer 22 and the top metal layer 26 must comprise superconducting materials, while the middle layer 24 must comprise a non-superconducting material. Further, the top metal layer 26 must be selective with respect to the middle layer 24 in an etch process, and the middle layer 24 must be selective with respect to the base metal layer 22 in an etch process. In one embodiment, the base metal layer 22 and the top metal layer 26 comprise niobium, while the middle layer 24 comprises aluminum oxide (Al₂O₃). The base metal layer 22 and the top metal layer 26 may also comprise other niobium class superconductors such as niobium-titanium nitride (Nb—Ti)N, niobium nitride (NbN), or any other superconducting material that meets the etch selectivity requirements discussed herein.

The wetting layer 18 and the etch-stop layer 20 may comprise titanium and aluminum, respectively. However, the wetting layer 18 and the etch-stop layer 20 may comprise any suitable material that is selective in an etch process with the base metal layer 22 and the resistor structure 16 while also being electrically conductive such that the base metal layer 22 electrically contacts the resistor structure 16 via the etch-stop layer 20 and the wetting layer 18. The wetting layer 18 must also be capable of smooth deposition onto the insulating layer 14 and the resistor structure 16.

The substrate 12 may comprise any suitable material such as silicon. The insulating layer 14 may similarly comprise any suitable material such as silicon oxide (SiO₂).

A thickness of the base metal layer 22 and the top metal layer 26 may be between 1 nm and 500 nm. The thickness of the resistor structure 16 should be at least 1.5 times less than the thickness of the base metal layer 22 and the top metal layer 26, and can be up to 5.0 times less, depending on a desired resistance of the resistor structure 16. A thickness of the wetting layer 18 may be between 1 nm and 100 nm. A thickness of the etch-stop layer 20 may be between 1 nm and 100 nm. A thickness of the middle layer 24 may be between 1 nm and 20 nm.

The Josephson junction structure 10 discussed herein is capable of being made in a high-volume manufacturing facility with existing semiconductor fabrication tooling (e.g., for complementary metal-oxide semiconductor (CMOS) devices). In addition to the constraints discussed above, the materials for the substrate 12, the insulating layer 14, the resistor structure 16, the wetting layer 18, the etch-stop layer 20, the base metal layer 22, the middle layer 24, and the top metal layer 26 may thus be chosen for their compatibility with a particular fabrication tooling scheme, which may restrict the available pool of materials for each of the above. For example, gold is generally not compatible with CMOS fabrication processes due to the affinity thereof for diffusion into semiconductor materials.

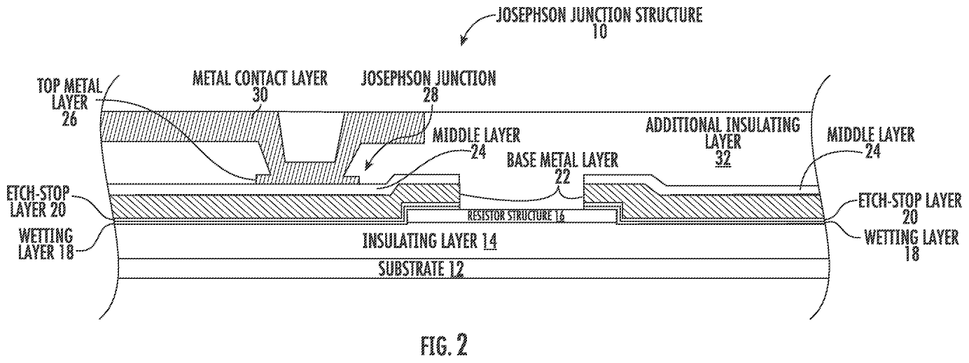

FIG. 2 shows a cross-sectional view of the Josephson junction structure 10 according to an additional embodiment of the present disclosure. The Josephson junction structure 10 shown in FIG. 2 is substantially similar to the one shown in FIG. 1, but further includes a metal contact layer 30 and an additional insulating layer 32. The metal contact layer 30 is patterned to contact the top metal layer 26 of the Josephson junction 28 in order to provide a signal path to/from the Josephson junction 28. While not shown, the metal contact layer 30 may be further patterned to provide a signal path to/from the base metal layer 22 directly and/or via the resistor structure 16 (e.g., by contacting the base metal layer 22 at the right side of the resistor structure 16 as shown).

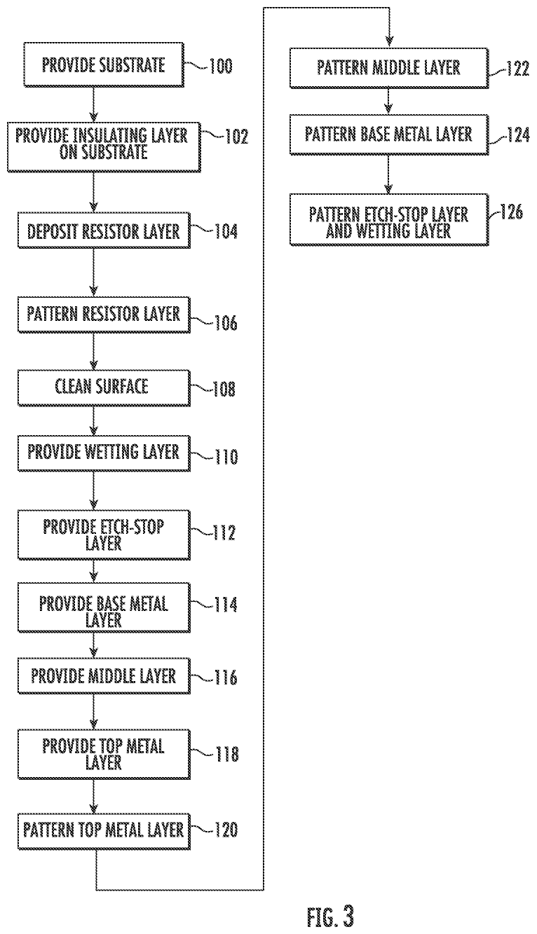

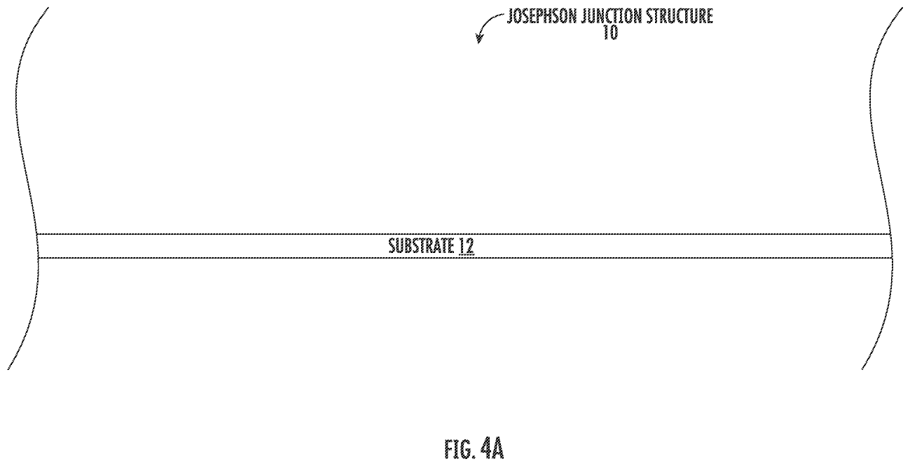

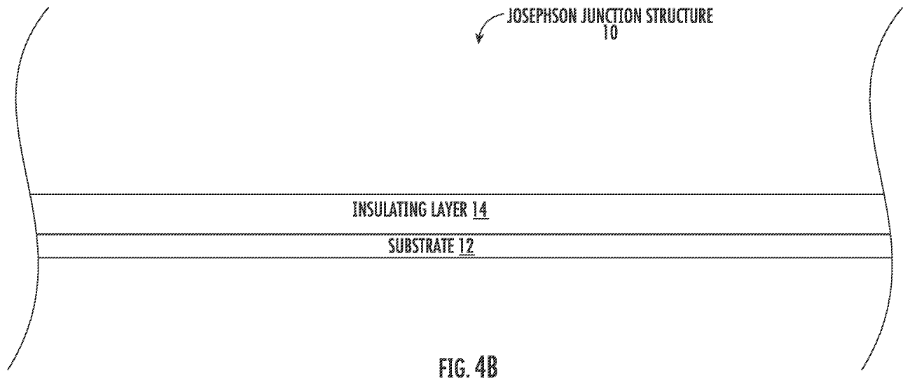

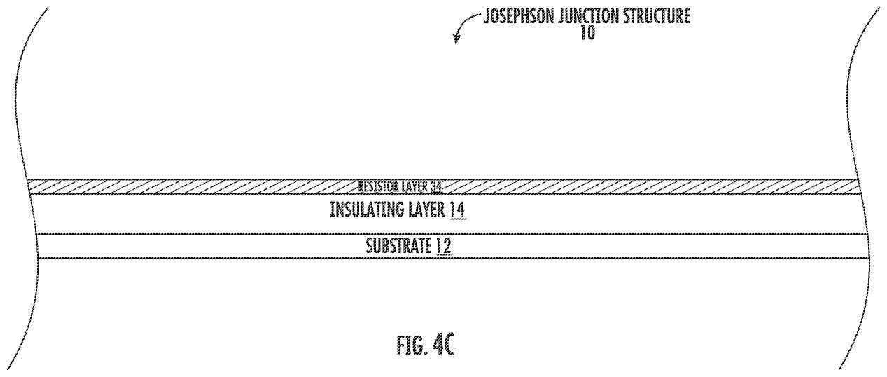

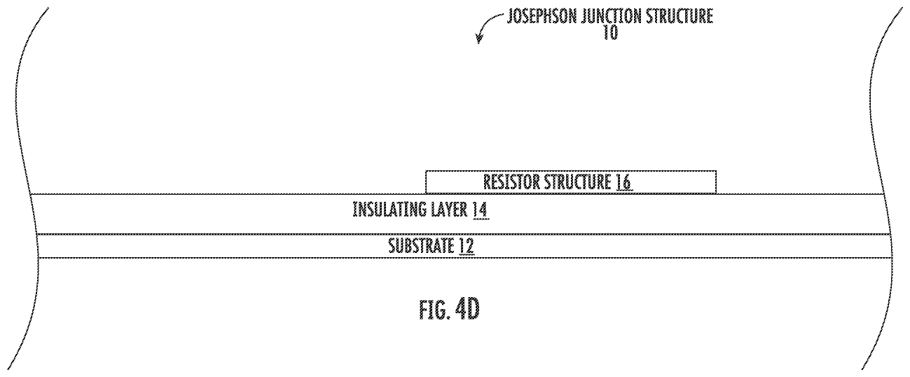

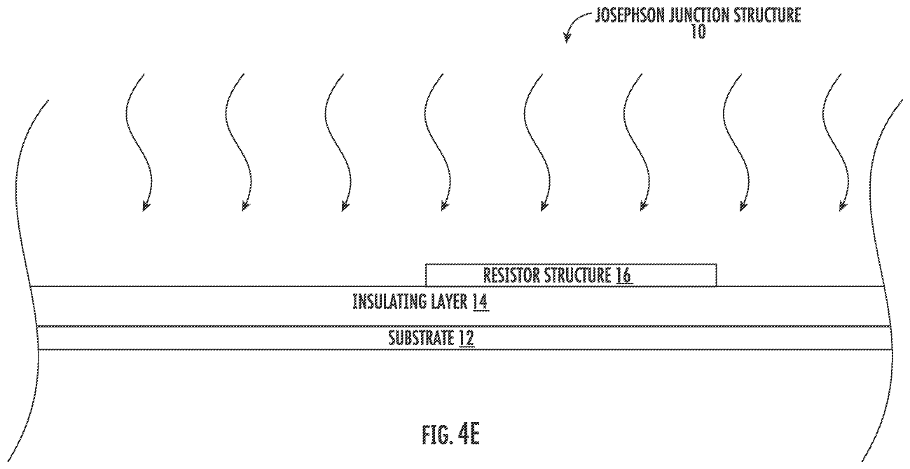

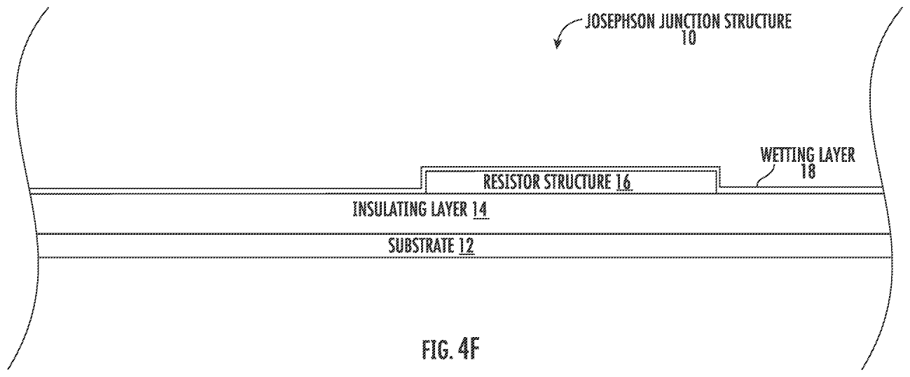

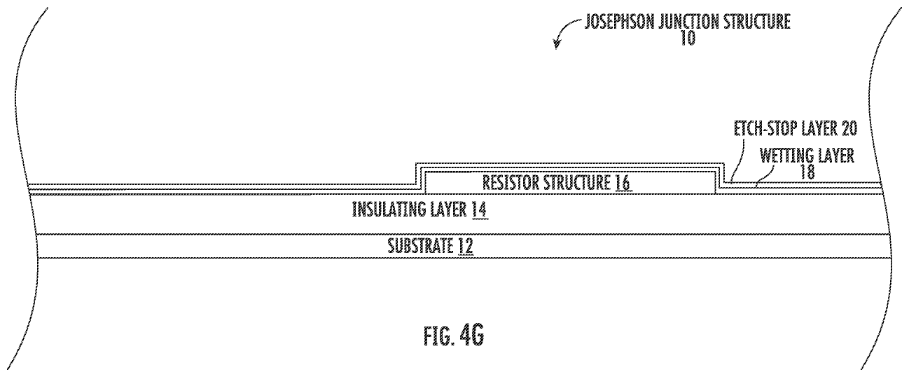

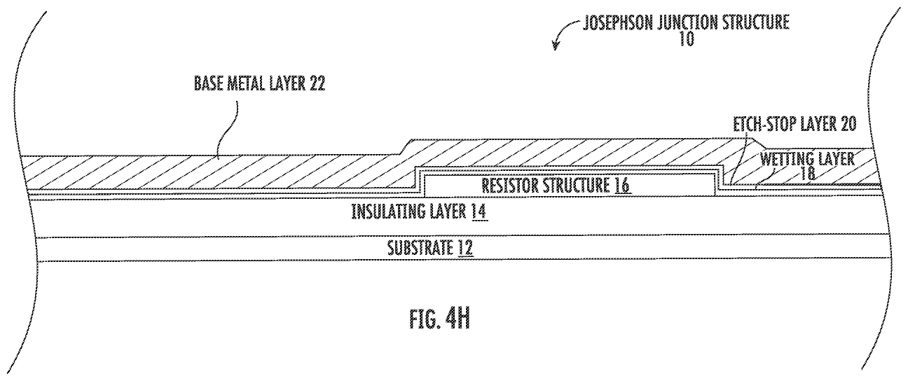

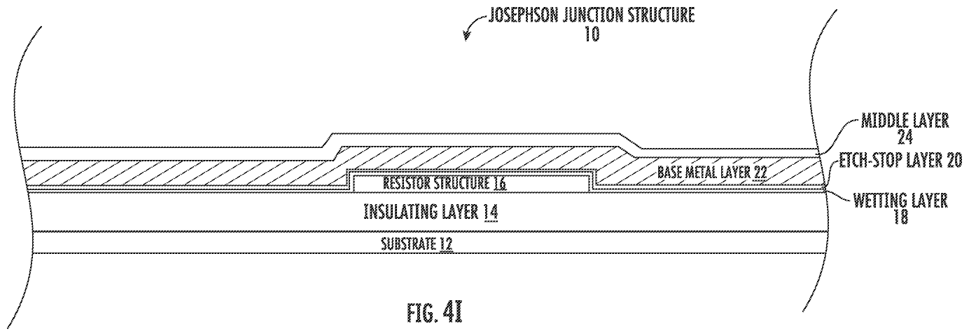

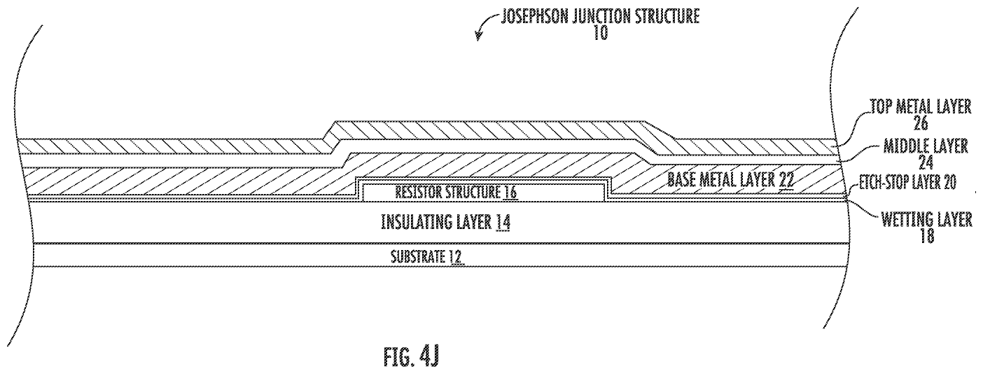

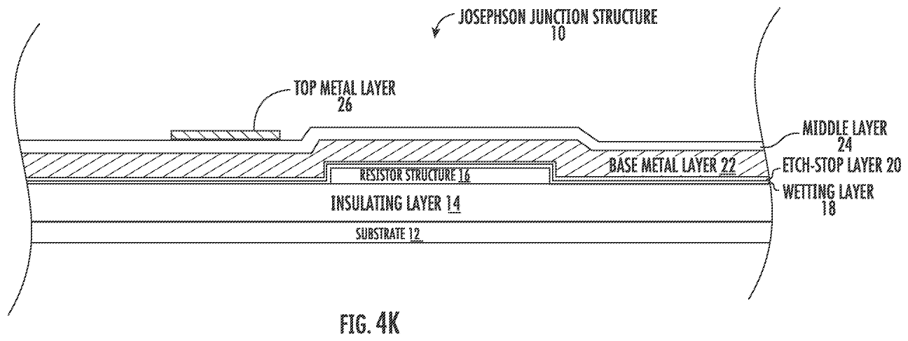

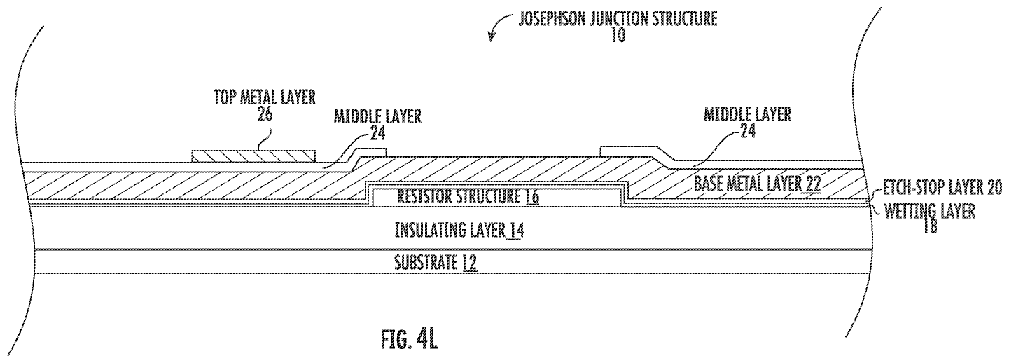

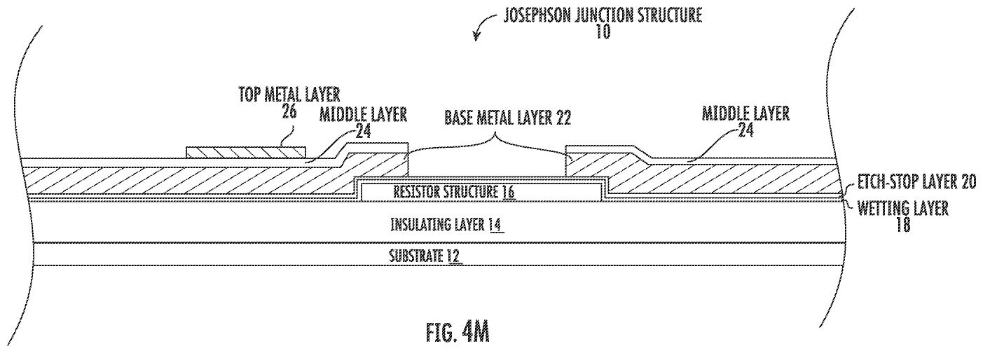

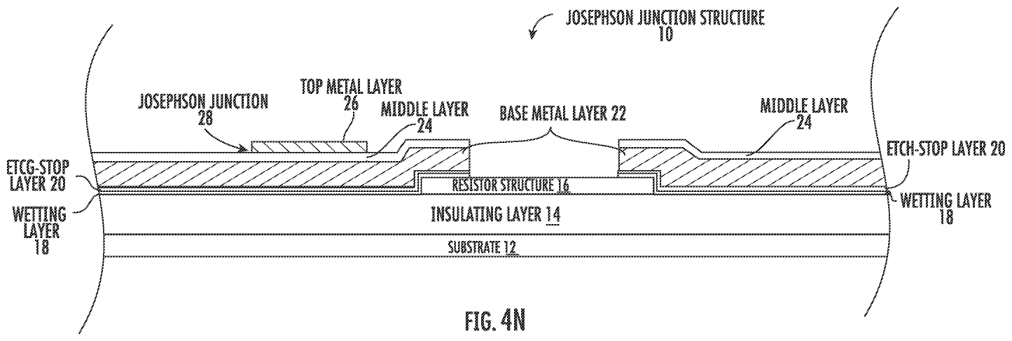

FIG. 3 is a flow diagram illustrating a method for manufacturing a Josephson junction structure according to one embodiment of the present disclosure. The steps described in FIG. 3 are illustrated sequentially in FIGS. 4A through 4N, and are therefore discussed along with FIG. 3. First, the substrate 12 is provided (step 100 and FIG. 4A). The substrate 12 may be provided by any suitable means. For example, the substrate 12 may be grown by a suitable crystal growth process and subsequently processed (e.g., cleaned, textured, etched) to provide a suitable shape, size, and surface quality. The insulating layer 14 is provided on the substrate 12 (step 102 and FIG. 4B). The insulating layer 14 may be provided by any suitable process, and in some embodiments may include multiple steps such as a deposition and subsequent oxidation.

A resistor layer 34 is provided on the insulating layer 14 (step 104 and FIG. 4C). The resistor layer 34 may be provided by any suitable means, including a deposition process such as physical vapor deposition (PVD). The resistor layer 34 is patterned to provide the resistor structure 16 (step 106 and FIG. 4D). The resistor layer 34 may be patterned by any suitable process. For example, the resistor layer 34 may be patterned using a mask and etch process, the details of which will be readily understood by those skilled in the art and thus are not included herein. As discussed above, the resistor layer 34 may comprise a material that is selective with respect to the insulating layer 14 in an etch process. Accordingly, the resistor layer 34 can be etched into a desired pattern to provide the resistor structure 16 without impacting the insulating layer 14.

Subsequent to the patterning of the resistor layer 34 to provide the resistor structure 16, the Josephson junction structure 10 is cleaned (step 108 and FIG. 4E). In particular, the exposed portions of the insulating layer 14 and the resistor structure 16 may be cleaned. As discussed above, the resistor structure 16 may comprise titanium tungsten (TiW) or tungsten, which may oxidize relatively easily. Cleaning the Josephson junction structure 10 may remove said oxidation and thus allow for higher quality surfaces to be achieved in the subsequently deposited layers. Notably, steps 108 through 120 below may be performed as an integrated process in a physical vapor deposition (PVD) chamber such that the Josephson junction structure 10 does not need to be removed from the chamber between steps. The cleaning step may prepare the Josephson junction structure 10 for the subsequent steps of the manufacturing process to provide high quality surfaces and thus electrical connections between the various parts thereof. In one embodiment, the cleaning process comprises a sputter clean. However, any suitable cleaning process may be performed.

The wetting layer 18 is then provided on the exposed portions of the insulating layer 14 and the resistor structure 16 (step 110 and FIG. 4F). The wetting layer may prepare the surface of the insulating layer 14 and the resistor structure 16 for deposition of the etch-stop layer 20, providing a barrier between the etch-stop layer 20 and the insulating layer 14. This may be important because the materials of the insulating layer 14 and the etch-stop layer 20 may interact in such a way that the etch-stop layer 20 would not otherwise form a smooth surface on the insulating layer 14. For example, aluminum tends to agglomerate on silicon oxide (SiO₂). Providing the wetting layer 18 may prevent said agglomeration and therefore allow for the formation of a smooth surface on which to build the Josephson junction 28 above. Since Josephson junction performance is directly correlated to the morphology or smoothness of the barrier layer between the superconducting layers, and the morphology of the barrier layer is dependent on the morphology of all of the layers below it, providing the wetting layer 18 may significantly improve the performance of the Josephson junction structure 10. The wetting layer 18 may be provided by any suitable means including a deposition process such as PVD.

The etch-stop layer 20 is provided on the wetting layer 18 (step 112 and FIG. 4G). As discussed above, the etch-stop layer 20 allows for patterning of the base metal layer 22 without requiring etch selectivity between the base metal layer 22 and the resistor structure 16, thereby opening up more combinations of materials and allowing the Josephson junction structure 10 to be manufactured in high volume facilities. The etch-stop layer 20 may be provided by any suitable means including a deposition process such as PVD.

The base metal layer 22 is provided on the etch-stop layer 20 (step 114 and FIG. 4H). The base metal layer 22 may be provided by any suitable means including a deposition process such as PVD. The middle layer 24 is provided on the base metal layer 22 (step 116 and FIG. 4I). The middle layer 24 may be provided by any suitable means including a deposition process such as PVD. Providing the middle layer 24 may comprise multiple steps including a deposition step and an oxidation step (e.g., to provide aluminum oxide as discussed above), the details of which will be readily understood by those skilled in the art and thus are not included herein. The top metal layer 26 is provided on the middle layer 24 (step 118 and FIG. 4J). The top metal layer 26 may be provided by any suitable means including a deposition process such as PVD.

While not shown in the flow diagram of FIG. 3, additional protective layers may be provided on the top metal layer 26. The additional protective layers may include, for example, silicon nitride (SiN). The additional protective layers may prevent oxidation of the top metal layer 26 during subsequent patterning and processing thereof, which may decrease manufacturing duration and complexity and allow for a more simplified fabrication process.

The top metal layer 26 is patterned (step 120 and FIG. 4K). The top metal layer 26 may be patterned by any suitable process. For example, the top metal layer 26 may be patterned using a mask and etch process, the details of which will be readily understood by those skilled in the art and thus are not included herein. Notably, the etch process used to pattern the top metal layer 26 is selective with respect to the middle layer 24. In one embodiment, the etch process used to pattern the top metal layer 26 utilizes an etching solution comprising fluorine. While etching solutions including fluorine (e.g., hydrofluoric acid) will readily etch niobium, they will not etch aluminum oxide (or do so much more slowly compared to niobium) and are therefore selective with respect to niobium and aluminum oxide. Accordingly, the top metal layer 26 can be etched into a desired pattern with minimal effect on the middle layer 24.

The middle layer 24 is patterned (step 122 and FIG. 4L). The middle layer 24 may be patterned by any suitable process. For example, the middle layer 24 may be patterned using a mask and etch process, the details of which will be readily understood by those skilled in the art and thus are not included herein. Notably, the etch process used to pattern the middle layer 24 is selective with respect to the base metal layer 22. In one embodiment, the etch process used to pattern the middle layer 24 utilizes an etching solution comprising chlorine. While etching solutions including chlorine (e.g., hydrochloric acid) will readily etch aluminum oxide, they will not etch niobium (or do so much more slowly compared to aluminum oxide) and are therefore selective with respect to aluminum oxide and niobium. Accordingly, the middle layer 24 can be etched into a desired pattern with minimal effect on the base metal layer 22.

The base metal layer 22 is patterned (step 124 and FIG. 4M). The base metal layer 22 may be patterned by any suitable process. For example, the base metal layer 22 may be patterned by a mask and etch process, the details of which will be readily understood by those skilled in the art and thus are not included herein. Notably, the etch process used to pattern the base layer 22 is selective with respect to the etch-stop layer 20. In one embodiment, the process used to pattern the base metal layer 22 utilizes an etching solution comprising fluorine. While etching solutions including fluorine (e.g., hydrofluoric acid) will readily etch niobium, they will not etch aluminum (or do so much more slowly compared to niobium) and are therefore selective with respect to niobium and aluminum. Accordingly, the base metal layer 22 can be etched into a desired pattern with minimal effect on the etch-stop layer 20 and thus the resistor structure 16 below.

The etch-stop layer 20 and wetting layer 18 are patterned (step 126 and FIG. 4N). The etch-stop layer 20 and wetting layer 18 may be patterned by any suitable process. For example, the etch-stop layer 20 and wetting layer 18 may be patterned by a mask and etch process, the details of which will be readily understood by those skilled in the art and thus are not included herein. Notably, the etch process used to pattern the etch-stop layer 20 and the wetting layer 18 is selective with respect to the resistor structure 16. In one embodiment, the process used to pattern the etch-stop layer 20 and the wetting layer 18 utilizes an etching solution comprising chlorine. While etching solutions including chlorine (e.g., hydrochloric acid) readily etch aluminum and titanium, they will not etch titanium tungsten or tungsten (or do so much more slowly compared to aluminum and titanium). Accordingly, the etch-stop layer 20 and the wetting layer 18 can be etched into a desired pattern with minimal impact on the resistor structure 16. In some embodiments, a single mask layer may be used to pattern multiple layers in the Josephson junction structure 10. For example, a single mask layer and multi-step etch process may be used to pattern the middle layer 24, the base metal layer 22, the etch-stop layer 20, and the wetting layer 18 in some embodiments.

As discussed above, contacts may be provided to various parts of the Josephson junction structure 10 such as those discussed above with respect to FIG. 2. The processes for doing so will be readily understood by those skilled in the art and thus are not included herein.

The process described above is compatible with high volume manufacturing such as processes designed for semiconductor devices, and in particular CMOS devices. The choice of materials allows for the creation of a desired pattern at each layer and thus provides a Josephson junction that is integrated with a support structure such as the resistor structure 16. Notably, the principles of the present disclosure are not limited to the integration of Josephson junctions with resistor structures, but rather are more broadly applicable to the integration of Josephson junctions with any support structures. The wetting layer 18 and the etch-stop layer 20 enable the integration of a Josephson junction with any desired support component (e.g., series resistors, other semiconductor devices such as diodes, transistors, and the like) using a similar process to the one discussed above.

While the above shows the base metal layer 22 directly on the etch-stop layer 20, which is directly on the wetting layer 18, which in turn is directly on the resistor structure 16, there may be additional intervening layers such as an additional inter-layer dielectric layer between the base metal layer 22 and the resistor structure 16. Vias or other metal connecting structures may be used to electrically couple the base metal layer 22 to the resistor structure 16. Further, while the resistor structure 16 is shown on the insulating layer 14 and described as being provided before manufacture of the Josephson junction 28, the resistor structure 16 may instead be provided on the additional insulating layer 30 such that the Josephson junction 28 is first provided and the resistor structure 16 is subsequently provided. In such an embodiment, the resistor structure 16 may contact the base metal layer 22 by any number of vias and/or additional metallization layers. The process for forming the Josephson junction 28 and the resistor structure 16 is the same as described above, with the order of manufacturing steps being changed. The selectivity of etch chemistries and selection of materials discussed throughout the present disclosure enables the manufacture of the Josephson junction structure 10 in any number of desired configurations.

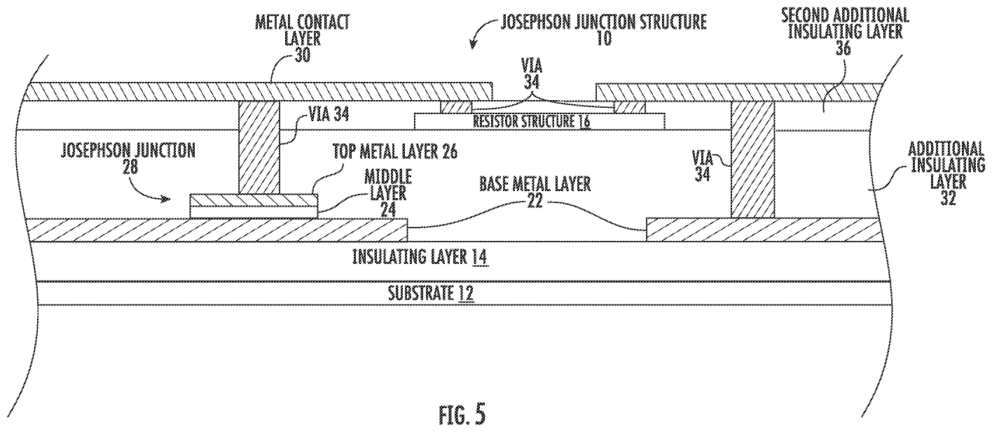

To illustrate, FIG. 5 shows the Josephson junction structure 10 according to an additional embodiment of the present disclosure. The Josephson junction structure 10 is substantially similar to that shown in FIG. 2 above, except that the resistor structure 16 is moved on top of the additional insulating layer 32 rather than on the insulating layer 14. The metal contact layer 30 electrically connects to the Josephson junction 16 using one or more vias 34, and further extends onto a second additional insulating layer 36. The metal contact layer 30 further electrically connects to the resistor structure 16 by one or more additional vias 34. FIG. 5 is meant to illustrate that the placement of the resistor structure 16 is flexible. That is, the principles of the present disclosure enable a number of Josephson junction structures 10 with support structures that can be provided and located in several different ways. The Josephson junction structure 10 shown in FIG. 5 can be manufactured according to the same principles discussed above with respect to FIGS. 3 and 4, with the order of steps changed.

Those skilled in the art will recognize improvements and modifications to the preferred embodiments of the present disclosure. All such improvements and modifications are considered within the scope of the concepts disclosed herein and the claims that follow.

What is claimed is:

1. A method for manufacturing a Josephson junction structure, the method comprising:
providing a substrate;
providing an insulating layer on the substrate;
providing a support structure on the insulating layer;
providing a wetting layer on the insulating layer and the support structure;
providing an etch-stop layer on the wetting layer;
providing a base metal layer on the etch-stop layer, the base metal layer comprising a superconducting material, wherein the base metal layer is in electrical contact with the support structure via the etch-stop layer and the wetting layer;
providing a middle layer on the base metal layer, the middle layer comprising a non-superconducting material;
providing a top metal layer on the middle layer, the top metal layer comprising a superconducting material;
patterning the top metal layer with a first etch process that is selective with respect to the middle layer;
patterning the middle layer with a second etch process that is selective with respect to the base metal layer;
patterning the base metal layer with a third etch process that is selective with respect to the etch-stop layer; and
patterning the etch-stop layer and the wetting layer with a fourth etch process that is selective with respect to the support structure, wherein the base metal layer, the middle layer, and the top metal layer provide a Josephson junction, which is electrically coupled to the support structure.

2. The method of claim 1 wherein the support structure is a resistor.

3. The method of claim 2 wherein providing the resistor comprises:
depositing a resistor layer on the insulating layer; and
patterning the resistor layer to provide the resistor.

4. The method of claim 3 wherein patterning the resistor layer to provide the resistor comprises performing an etch process on the resistor layer that is selective with respect to the insulating layer.

5. The method of claim 2 wherein the resistor is a shunt resistor.

6. The method of claim 2 wherein the resistor comprises one of titanium tungsten and tungsten.

7. The method of claim 6 wherein:
the base metal layer and the top metal layer comprise niobium; and
the middle layer comprises aluminum oxide.

8. The method of claim 7 wherein:
the wetting layer comprises titanium; and
the etch-stop layer comprises aluminum.

9. The method of claim 8 wherein:
a thickness of the wetting layer is less than 100 nm; and
a thickness of the etch-stop layer is less than 100 nm.

10. The method of claim 9 wherein:
the first etch process and the third etch process utilize an etching solution comprising fluorine; and
the second etch process and the fourth etch process utilize an etching solution comprising chlorine.

11. The method of claim 1 further comprising, before providing the wetting layer on the insulating layer and the support structure, performing a pre-cleaning process to clean the exposed portions of the insulating layer and the support structure.

12. The method of claim 11 wherein the pre-cleaning process comprises sputter cleaning.

13. The method of claim 1 wherein the wetting layer, the etch-stop layer, the base metal layer, the middle layer, and the top metal layer are deposited using physical vapor deposition.

14. A Josephson junction structure comprising:
a substrate;
an insulating layer on the substrate;
a support structure on the insulating layer;
a wetting layer on the insulating layer and a portion of the support structure;
an etch-stop layer on the wetting layer;
a base metal layer on the etch-stop layer, the base metal layer comprising a superconducting material, wherein the base metal layer is in electrical contact with the support structure via the etch-stop layer and the wetting layer;
a middle layer on the base metal layer, the middle layer comprising a non-superconducting material; and
a top metal layer on the middle layer, the top metal layer comprising a superconducting material, wherein the base metal layer, the middle layer, and the top metal layer provide a Josephson junction, which is electrically coupled to the support structure.

15. The Josephson junction structure of claim 14 wherein the support structure is a resistor.

16. The Josephson junction structure of claim 15 wherein the resistor is a shunt resistor.

17. The Josephson junction structure of claim 15 wherein the resistor comprises one of titanium tungsten and tungsten.

18. The Josephson junction structure of claim 17 wherein:
the base metal layer and the top metal layer comprise niobium; and
the middle layer comprises aluminum oxide.

19. The Josephson junction structure of claim 18 wherein:
the wetting layer comprises titanium; and
the etch-stop layer comprises aluminum.

20. The Josephson junction structure of claim 15 wherein:
a thickness of the wetting layer is less than 100 nm; and
a thickness of the etch-stop layer is less than 100 nm.
